(19) United States
(12) Patent Application Publication
(10) Pub. No.: US 2026/0075954 A1
(43) Pub. Date: Mar. 12, 2026

(54) SEMICONDUCTOR INTEGRATED CIRCUIT DEVICE

(71) Applicant: Socionext Inc., Kanagawa (JP)

(72) Inventor: Masatomo ICHIOKA, Yokohama-shi (JP)

(21) Appl. No.: 19/392,734

(22) Filed: Nov. 18, 2025

Related U.S. Application Data
(63) Continuation of application No. PCT/JP2023/037380, filed on Oct. 16, 2023.

(51) Int. Cl. H10D 89/10; G05F 3/26; H01L 23/528; H10D 30/00; H10D 30/43; H10D 62/10; H10D 84/85

(52) U.S. Cl. CPC H10D 89/10; G05F 3/262; H10W 20/43; H10D 30/43; H10D 30/502; H10D 62/121; H10D 84/851

(57) ABSTRACT

A semiconductor integrated circuit device includes first and second transistors constituting a current mirror. The transistors are each constituted by a plurality of units each having an active region. Dummy transistors are each constituted by a plurality of units each having an active region, the plurality of units being placed at positions overlapping the corresponding units of the first and second transistors in planar view. The active regions of the first and second transistors are formed line-symmetrically. The active regions of the dummy transistors are also formed line-symmetrically. In the dummy transistors, sources and drains at symmetric positions have the same electrical connection state.

### CROSS-REFERENCE TO RELATED APPLICATIONS

This is a continuation of International Application No. PCT/JP2023/037380 filed on Oct. 16, 2023. The entire disclosure of this application is incorporated by reference herein.

### BACKGROUND

The present disclosure relates to a layout structure of a semiconductor integrated circuit device.

For higher integration of a semiconductor integrated circuit device, there is available a complementary field effect transistor (CFET) technique in which transistors are stacked one upon another in the direction normal to the substrate. The direction normal to the substrate is herein called the depth direction. Moreover, for higher integration of a semiconductor integrated circuit device, there is proposed a technique in which interconnects are provided right under transistors and connected to source/drain regions of the transistors.

US Patent Application Publication No. 2022/0344255 discloses a structure of a standard cell using the CFET technique and interconnects right under transistors.

An analog circuit handling an analog signal is one of basic circuits constituting a semiconductor integrated circuit. A current mirror circuit is one type of the analog circuit. The current mirror circuit is a circuit that mirrors (copies) a reference current to obtain an output current, and also a circuit capable of retaining the output current with respect to the reference current at a predetermined ratio (e.g., one to one, two to one, three to one, and a half to one). The output current from the current mirror circuit is required to have high precision as a bias current inside a semiconductor integrated circuit. To prevent variations in the ratio of the output current to the reference current, it is necessary to prevent variations between circuits caused by variations in layout.

In the cited patent document, however, no examination has been made on the layout structure using CFETs for a current mirror circuit.

An objective of the present disclosure is presenting a layout structure using CFETs for a current mirror circuit.

### SUMMARY

According to the first mode of the disclosure, a semiconductor integrated circuit device includes: a first transistor of a first conductivity type having a source connected to power supply and a gate and a drain connected to a first node; a second transistor of the first conductivity type located at a same position as the first transistor in a depth direction and having a source connected to power supply, a gate connected to the first node, and a drain connected to an output terminal; a first dummy transistor of a second conductivity type located at a different position from the first transistor in the depth direction and having a gate connected to the first node; and a second dummy transistor of the second conductivity type located at a same position as the first dummy transistor in the depth direction and having a gate connected to the first node, wherein the first and second transistors are each constituted by a plurality of units each having an active region forming a channel, source, and drain of a transistor, the first and second dummy transistors are each constituted by a plurality of units each having an active region forming a channel, source, and drain of a transistor, the plurality of units being placed at positions overlapping the corresponding units constituting the first and second transistors in planar view, the active region of the first transistor and the active region of the second transistor are formed line-symmetrically with respect to a predetermined straight line as an axis in planar view, the active region of the first dummy transistor and the active region of the second dummy transistor are formed line-symmetrically with respect to the predetermined straight line in planar view, and in the first and second dummy transistors, the sources and the drains located at symmetric positions with respect to the predetermined straight line have a same electrical connection state.

According to the above mode, the semiconductor integrated circuit device includes first and second transistors constituting a current mirror. The first and second transistors are each constituted by a plurality of units each having an active region. First and second dummy transistors are formed at positions different from the first and second transistors in the depth direction. The first and second dummy transistors are each constituted by a plurality of units each having an active region and placed at positions overlapping the corresponding units of the first and second transistors in planar view. The active region of the first transistor and the active region of the second transistor are formed line-symmetrically with respect to a predetermined straight line as an axis in planar view. The active region of the first dummy transistor and the active region of the second dummy transistor are also formed line-symmetrically with respect to the same predetermined straight line. In the first and second dummy transistors, sources and drains at symmetric positions have the same electrical connection state. Therefore, since variations in the characteristics of the first and second transistors constituting a current mirror are prevented, variations in the ratio of the output current to the reference current can be prevented.

According to the present disclosure, a layout structure using CFETs capable of preventing variations in the ratio of an output current to a reference current can be implemented for a current mirror circuit.

### BRIEF DESCRIPTION OF THE DRAWINGS

FIG. 1 shows a circuit configuration example of a current mirror according to the first embodiment.

FIG. 2 is a plan view showing a layout structure example of the current mirror shown in FIG. 1, illustrating the structure of an upper part.

FIG. 3 is a plan view showing the layout structure example of the current mirror shown in FIG. 1, illustrating the structure of a lower part.

FIGS. 4A-4B are cross-sectional views of the layout structure shown in FIGS. 2 and 3.

FIG. 5 shows an alteration of the layout structure of FIG. 3.

FIG. 6 shows an alteration of the layout structure of FIG. 2.

FIG. 7 shows a circuit configuration example of a current mirror according to the second embodiment.

FIG. 8 is a plan view showing a layout structure example of the current mirror shown in FIG. 7, illustrating the structure of an upper part.

FIG. 9 is a plan view showing the layout structure example of the current mirror shown in FIG. 7, illustrating the structure of a lower part.

FIG. 10 is a plan view showing another layout structure example of the current mirror shown in FIG. 1, illustrating the structure of an upper part.

FIG. 11 is a plan view showing another layout structure example of the current mirror shown in FIG. 1, illustrating the structure of a lower part.

FIG. 12 is a plan view showing yet another layout structure example of the current mirror shown in FIG. 1, illustrating the structure of an upper part.

FIG. 13 is a plan view showing yet another layout structure example of the current mirror shown in FIG. 1, illustrating the structure of a lower part.

### DETAILED DESCRIPTION

Embodiments of the present disclosure will be described hereinafter with reference to the accompanying drawings. In the following embodiments, the semiconductor integrated circuit device includes nanosheet field effect transistors (FETs). According to the present disclosure, however, transistors included in the semiconductor integrated circuit device are not limited to nanosheet FETs.

As used herein, “VDD” and “VSS” refer to the power supply voltages or the power supplies themselves. As used herein, an expression indicating that sizes such as widths are identical, like the “same wiring width,” is to be understood as including a range of manufacturing variations.

### First Embodiment

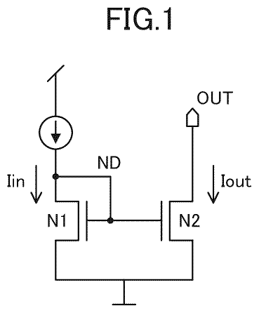

FIG. 1 is a circuit diagram showing a circuit configuration example of a current mirror according to the first embodiment. The current mirror is one type of the analog circuit. The current mirror of FIG. 1 includes n-type transistors N1 and N2 and a current source.

The transistor N1 is connected to the current source at its drain and to the power supply VSS at its source. The transistor N2 is connected to an output terminal OUT at its drain and to the power supply VSS at its source. The transistors N1 and N2 share the gate at a node ND. Also, the node ND is connected to the drain of the transistor N1.

The current source is specifically constituted by a p-type transistor that is supplied with a bias voltage at its gate, for example. Note that the circuit implementing the current source is not limited to this.

In the current mirror of FIG. 1, a current Iin (reference current) flowing from the drain to source of the transistor N1 is copied (mirrored) to a current Iout (output current) flowing from the drain to source of the transistor N2 according to the size ratio between the transistors N1 and N2. In this embodiment, since the transistors N1 and N2 are assumed to have the same size, Iout=Iin. The current Iout is output from the output terminal OUT.

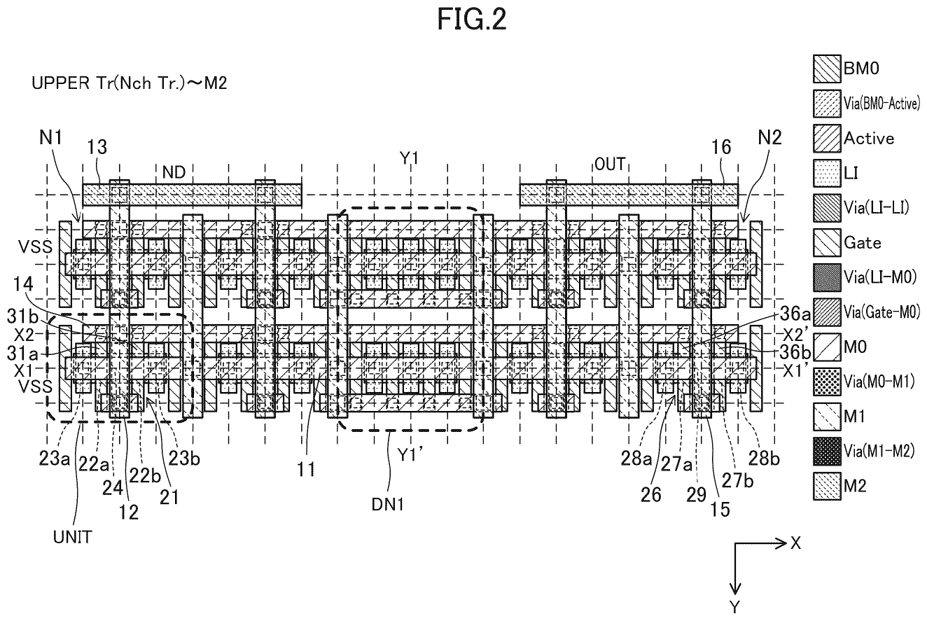

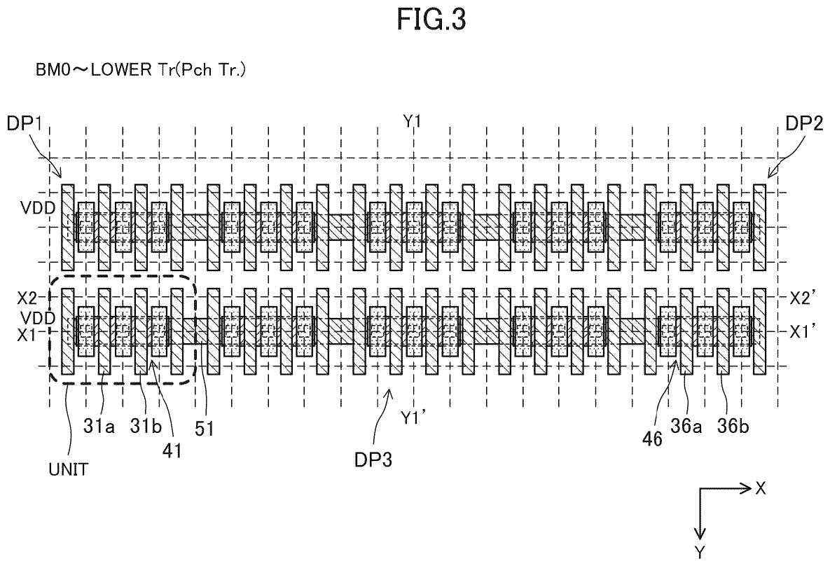

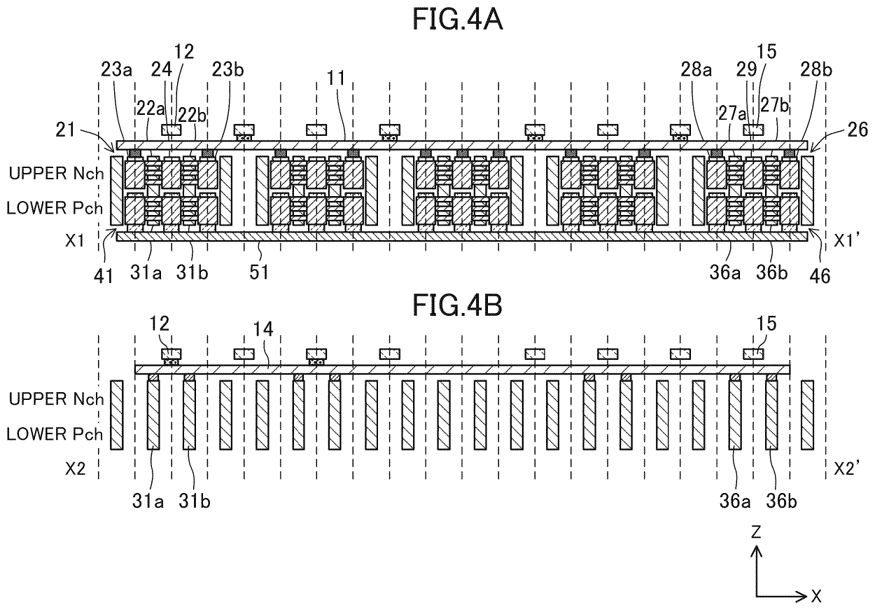

FIGS. 2 to 4B are views showing a layout structure example, using CFETs, of the current mirror of FIG. 1. Specifically, FIG. 2 is a plan view of an upper part that is a part including upper transistors formed in the portion farther from the substrate, FIG. 3 is a plan view of a lower part that is a part including lower transistors formed in the portion closer to the substrate, FIG. 4A is a cross-sectional view taken along line X1-X1′ in FIGS. 2 and 3, and FIG. 4B is a cross-sectional view taken along line X2-X2′ in FIGS. 2 and 3. In this layout structure example, n-type nanosheet FETs are formed in the upper part, and p-type nanosheet FETs are formed in the lower part. The transistors N1 and N2 in the circuit diagram of FIG. 1 are formed in the upper part. In the lower part, dummy transistors that are not illustrated in the circuit diagram of FIG. 1 are formed.

Note that, in the plan views such as FIG. 2, the horizontal direction in the figure is hereinafter referred to as an X direction, the vertical direction in the figure as a Y direction, and the direction normal to the substrate plane as a Z direction (corresponding to the depth direction). Also, hereinafter, the same components are denoted by the same reference characters, and description of such components may be omitted.

The transistors N1 and N2 are formed on the left and right sides, respectively, in FIG. 2. In FIG. 2, the transistors N1 and N2 are each constituted by 2×2 “units” arranged in an array. The unit here refers to a configuration formed of two parallel-connected transistors. Note however that the configuration of the unit is not limited to the one illustrated here. The planar layouts of the transistors N1 and N2 are line-symmetric with respect to line Y1-Y1′ extending in the Y direction.

The configuration of the transistor N1 will be described focusing mainly on the unit on the lower left in the figure.

In FIG. 2, in an M0 layer, an interconnect 11 extending in the X direction is formed from the transistor N1 over to the transistor N2. The M0 layer is an interconnect layer in the surface-side portion of a semiconductor chip. The M0 interconnect 11 is a power line supplying VSS. In an M1 layer located above the M0 layer, an interconnect 12 extending in the Y direction is formed. In an M2 layer located above the M1 layer, an interconnect 13 extending in the X direction is formed on the upper side of the transistor N1 in the figure. The M2 interconnect 13 corresponds to the node ND. The M1 interconnect 12 is connected to the M2 interconnect 13 through a via.

Below the M0 interconnect 11, formed is an active region 21 forming the channels, sources, and drains of n-type nanosheet FETs that are to be the transistor N1.

The active region 21 includes nanosheets 22a and 22b that are to be the channels of the n-type nanosheet FETs. Portions 23a and 23b that are to be the sources of the n-type nanosheet FETs in the active region 21 are connected to the M0 interconnect 11 through local interconnects and vias. Also, a portion 24 that is to be the drains of the n-type nanosheet FETs in the active region 21 is connected to the M1 interconnect 12 through a local interconnect, a via, an M0 interconnect, and a via.

Note that, in the active region, portions that are to be the source and the drain on both sides of a nanosheet are formed by epitaxial growth from the nanosheet, for example.

Gate interconnects 31a and 31b extend in the Y direction and also extend in the Z direction from the upper part over to the lower part. The gate interconnects 31a and 31b surround the peripheries of the nanosheets 22a and 22b, respectively, in the Y direction and the Z direction through gate insulating films (not shown). The gate interconnects 31a and 31b are to be the gate of the transistor N1, and connected to an interconnect 14 in the M0 layer through vias. The M0 interconnect 14 extends in the X direction from the transistor N1 over to the transistor N2. The M0 interconnect 14 is connected to the M1 interconnect 12 through a via.

The configuration of the transistor N2 will be described focusing mainly on the unit on the lower right in the figure.

In the M1 layer, an interconnect 15 extending in the Y direction is formed. In the M2 layer, an interconnect 16 extending in the X direction is formed on the upper side of the transistor N2 in the figure. The M2 interconnect 16 corresponds to the output terminal OUT. The M1 interconnect 15 is connected to the M2 interconnect 16 through a via.

Below the M0 interconnect 11, formed is an active region 26 forming the channels, sources, and drains of n-type nanosheet FETs that are to be the transistor N2.

The active region 26 includes nanosheets 27a and 27b that are to be the channels of the n-type nanosheet FETs. Portions 28a and 28b that are to be the sources of the n-type nanosheet FETs in the active region 26 are connected to the M0 interconnect 11 through local interconnects and vias. Also, a portion 29 that is to be the drains of the n-type nanosheet FETs in the active region 26 is connected to the M1 interconnect 15 through a local interconnect, a via, an M0 interconnect, and a via.

Gate interconnects 36a and 36b extend in the Y direction and also extend in the Z direction from the upper part over to the lower part. The gate interconnects 36a and 36b surround the peripheries of the nanosheets 27a and 27b, respectively, in the Y direction and the Z direction through gate insulating films (not shown). The gate interconnects 36a and 36b are to be the gate of the transistor N2, and connected to the interconnect 14 in the M0 layer through vias. The M0 interconnect 14 is however not connected to the M1 interconnect 15.

In FIG. 3, an active region 41 forming the channels, sources, and drains of p-type nanosheet FETs is formed at a position overlapping the active region 21 of the transistor N1 in planar view. Also, an active region 46 forming the channels, sources, and drains of p-type nanosheet FETs is formed at a position overlapping the active region 26 of the transistor N2 in planar view. The active regions 41 and 46 constitute dummy transistors DP1 and DP2, respectively.

In a BM0 layer, an interconnect 51 extending in the X direction is formed. The BM0 layer is an interconnect layer in the backside portion of the semiconductor chip. The BM0 interconnect 51 is a power line supplying VDD.

The gate interconnects 31a and 31b surround the peripheries of nanosheets in the active region 41 in the Y direction and the Z direction through gate insulating films (not shown). The gate interconnects 36a and 36b surround the peripheries of nanosheets in the active region 46 in the Y direction and the Z direction through gate insulating films (not shown).

Portions that are to be sources and drains in the active region 41 are connected to the BM0 interconnect 51 through vias. Portions that are to be sources and drains in the active region 46 are connected to the BM0 interconnect 51 through vias.

In addition, in FIG. 2, a dummy transistor DN1 is formed in a region between the transistor N1 and the transistor N2. Also, in FIG. 3, a dummy transistor DP3 is formed at a position overlapping the dummy transistor DN1 in planar view.

The layout structure shown in FIGS. 2 to 4B has the following features.

The layouts of the transistors N1 and N2 constituting the current mirror are formed line-symmetrically with respect to the line Y1-Y1′ as the symmetric axis.

Specifically, both the transistors N1 and N2 are constituted by 2×2 units arranged in an array where each unit is formed of two transistors connected in parallel. Therefore, the transistors N1 and N2 have the same transistor size, and therefore Iout=Iin. Also, in the transistors N1 and N2, the gates, the sources, and the drains constituting the transistors are placed symmetrically. The vias connected to the gates, the sources, and the drains are also placed symmetrically. The interconnects (local interconnects and M0 interconnects) connected to the transistors and the vias between the interconnects are also placed symmetrically. Note however that, from the standpoint of circuit configuration, no via is placed for connecting the M0 interconnect 14 and the M1 interconnect 15 in the transistor N2. Also, the M2 interconnect 13 corresponding to the node ND and the M2 interconnect 16 corresponding to the output terminal OUT are placed symmetrically with respect to the line Y1-Y1′ as the symmetric axis.

Having the symmetric arrangement as described above, since variations in characteristics between the transistors N1 and N2 are prevented, it is possible to prevent variations in the ratio of the output current to the reference current.

Also, the p-type dummy transistors DP1 and DP2 formed under the transistors N1 and N2 are formed line-symmetrically with respect to the line Y1-Y1′ as the symmetric axis.

Specifically, like the transistors N1 and N2, the dummy transistors DP1 and DP2 are each constituted by 2×2 units arranged in an array where each unit is formed of two transistors connected in parallel. The gates are formed integrally with the gates of the transistors N1 and N2 in the upper part, and therefore connected to the same node ND as the transistors N1 and N2. The sources and the drains are all connected to the BM0 interconnect 51 supplying VDD through vias. The interconnects and the vias connected to the dummy transistors DP1 and DP2 are placed line-symmetrically with respect to the line Y1-Y1′ as the symmetric axis.

As described above, by forming the dummy transistors DP1 and DP2 in the lower part, above which the transistors N1 and N2 are formed, symmetrically in their circuits and layouts, variations in the finished sizes of the transistors including the transistors N1 and N2 in the upper part are prevented.

Moreover, since the gates of the transistors N1 and N2 and the underlying dummy transistors DP1 and DP2 are integrally formed, for the gates of the n-type nanosheet FETs constituting the transistors N1 and N2, the gates of their underlying p-type nanosheet FETs also work as loads. In the above configuration, however, since the dummy transistors DP1 and DP2 are also formed symmetrically in their circuits and layouts, variations in loads can be prevented.

From the features described above, in the current mirror circuit, variations in the ratio of the output current to the reference current can be prevented.

As described above, according to this embodiment, the semiconductor integrated circuit device includes the transistors N1 and N2 constituting a current mirror. The transistors N1 and N2 are each constituted by a plurality of units each having an active region. The dummy transistors DP1 and DP2 are formed at positions different from the transistors N1 and N2 in the depth direction. The dummy transistors DP1 and DP2 are each constituted by a plurality of units each having an active region and placed at positions overlapping the units constituting the transistors N1 and N2 in planar view. The active region of the transistor N1 and the active region of the transistor N2 are formed line-symmetrically with respect to the straight line Y1-Y1′ in planar view. The active region of the dummy transistor DP1 and the active region of the dummy transistor DP2 are also formed line-symmetrically with respect to the straight line Y1-Y1′. Also, in the dummy transistors DP1 and DP2, the sources and the drains at the symmetric positions have the same electrical connection state. With this configuration, since variations in the characteristics of the transistors N1 and N2 constituting the current mirror are prevented, it is possible to prevent variations in the ratio of the output current to the reference current.

### Alteration 1

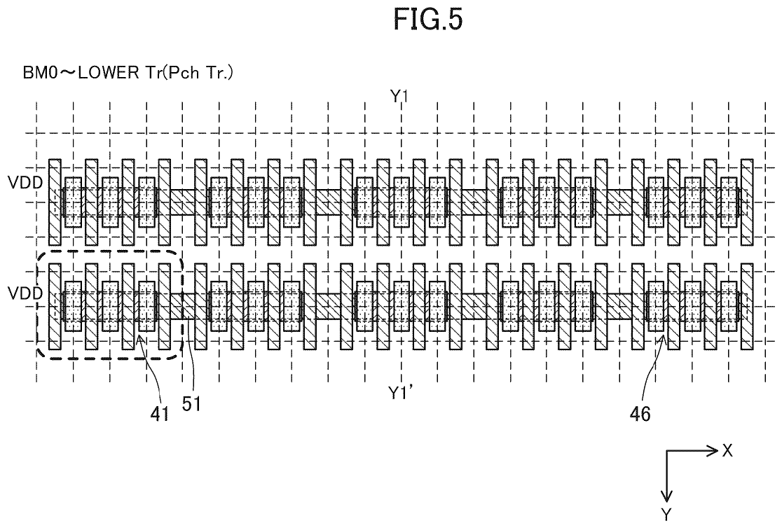

FIG. 5 is a view showing a layout structure according to Alteration 1, which is a plan view of the lower part including lower transistors. The layout structure of FIG. 5 is roughly the same as that of FIG. 3, except that the active regions 41 and 46 are not connected to the BM0 interconnect 51. That is, all of the sources and drains of the dummy transistors DP1 and DP2 are floating. The plan view of the upper part is the same as that in the embodiment described above.

In this alteration, also, the dummy transistors DP1 and DP2 in the lower part, above which the transistors N1 and N2 are formed, are formed symmetrically in their circuits and layouts. Therefore, similar effects to those in the above embodiment can be obtained.

### Alteration 2

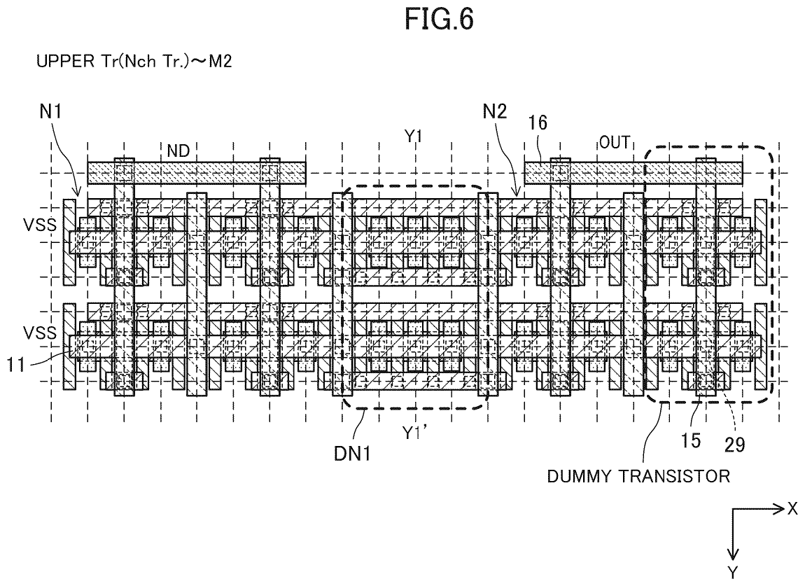

FIG. 6 is a view showing a layout structure according to Alteration 2, which is a plan view of the upper part including upper transistors. The layout structure of FIG. 6 is roughly the same as that of FIG. 2, except that, out of the 2×2 units constituting the transistor N2, two units of transistors on the right in the figure are dummy transistors. The plan view of the lower part is the same as that in the embodiment described above.

Specifically, in the two units on the right in the figure, the M1 interconnect 15 connected to the portions 29 that are to be the drains is not connected to the M2 interconnect 16 corresponding to the output terminal OUT. Instead, the M1 interconnect 15 is connected to the M0 interconnects 11 supplying VSS. The other configurations and connections are not changed. That is, in the two units on the right in the figure, the drains are connected to VSS, not to the output terminal OUT, whereby the transistors in the two units are dummy transistors.

In this alteration, the transistor size of the transistor N2 is half that of the transistor N1. Therefore, the relationship between the reference current and the output current is Iout=0.5×Iin.

In this alteration, also, since the units constituting the transistors N1 and N2 are formed line-symmetrically in their layouts, similar effects to those in the above embodiment are obtained. Also, since the configuration of the dummy transistors formed in the lower part is similar to that in the above embodiment, similar effects to those in the embodiment are obtained.

While two units on the right in the figure are changed to dummy transistors in the transistor N2 in FIG. 6, the units changed to dummy transistors are not limited to these. For example, in the transistor N2, two units on the left in the figure may be changed to dummy transistors.

Also, in the transistor N1, some of the units may be changed to dummy transistors.

The units changed to dummy units may be omitted from the layout structure.

### Second Embodiment

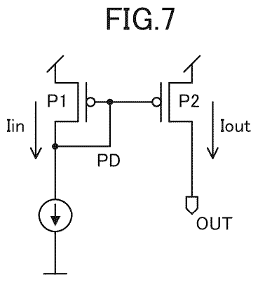

FIG. 7 is a circuit diagram showing a circuit configuration example of a current mirror according to the second embodiment. The current mirror of FIG. 7 includes p-type transistors P1 and P2 and a current source.

The transistor P1 is connected to the current source at its drain and to the power supply VDD at its source. The transistor P2 is connected to an output terminal OUT at its drain and to the power supply VDD at its source. The transistors P1 and P2 share the gate at a node PD. Also, the node PD is connected to the drain of the transistor P1.

The current source is specifically constituted by an n-type transistor that is supplied with a bias voltage at its gate, for example. Note that the circuit implementing the current source is not limited to this.

In the current mirror of FIG. 7, as in the current mirror of FIG. 1, a current Iin (reference current) flowing from the source to drain of the transistor P1 is copied (mirrored) to a current Iout (output current) flowing from the source to drain of the transistor P2 according to the size ratio between the transistors P1 and P2. In this embodiment, since the transistors P1 and P2 are assumed to have the same size, Iout=Iin. The current Iout is output from the output terminal OUT.

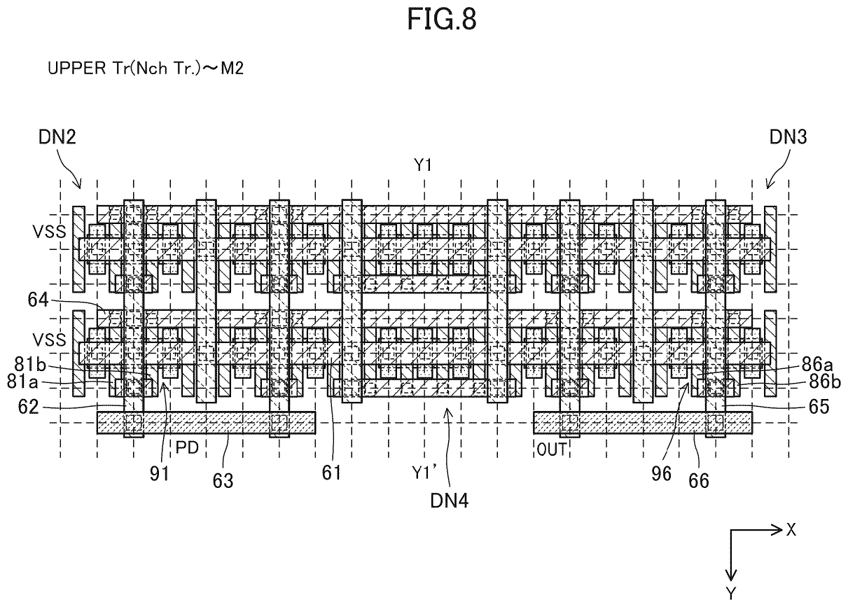

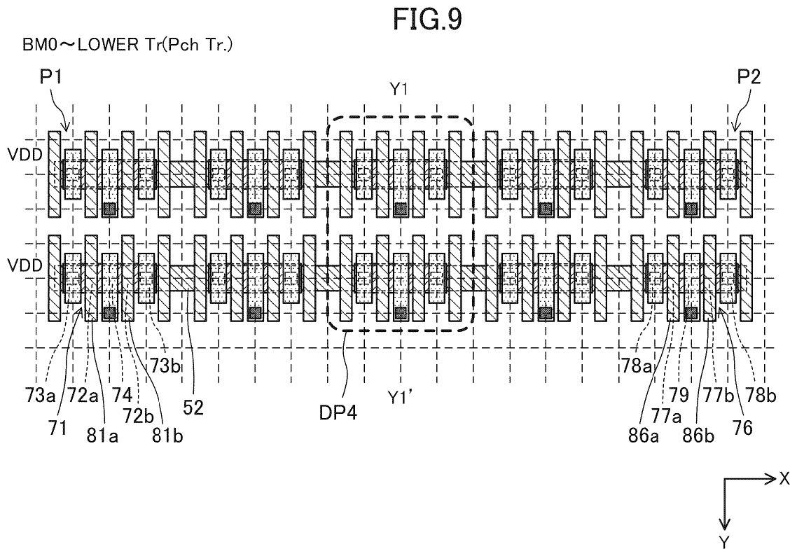

FIGS. 8 and 9 are views showing a layout structure example, using CFETs, of the current mirror of FIG. 7, where FIG. 8 is a plan view of an upper part and FIG. 9 is a plan view of a lower part. In this layout structure example, n-type nanosheet FETs are formed in the upper part, and p-type nanosheet FETs are formed in the lower part. Note that, since the cross-sectional structure is easily known by analogy from the description in the first embodiment, illustration thereof is omitted here. The transistors P1 and P2 in the circuit diagram of FIG. 7 are formed in the lower part. In the upper part, dummy transistors that are not illustrated in the circuit diagram of FIG. 7 are formed.

The configuration of the transistor P1 will be described focusing mainly on the unit on the lower left in the figure.

In FIG. 8, in the M0 layer, an interconnect 61 extending in the X direction is formed from a dummy transistor DN2 over to a dummy transistor DN3. The M0 interconnect 61 is a power line supplying VSS. In the M1 layer, an interconnect 62 extending in the Y direction is formed. In the M2 layer, an interconnect 63 extending in the X direction is formed on the lower side in the figure. The M2 interconnect 63 corresponds to the node PD. The M1 interconnect 62 is connected to the M2 interconnect 63 through a via.

In FIG. 9, in the BM0 layer, an interconnect 52 extending in the X direction is formed from the transistor P1 over to the transistor P2. The BM0 interconnect 52 is a power line supplying VDD.

An active region 71 forming the channels, sources, and drains of p-type nanosheet FETs that are to be the transistor P1 is formed at a position overlapping the BM0 interconnect 52 in planar view.

The active region 71 includes nanosheets 72a and 72b that are to be the channels of the p-type nanosheet FETs. Portions 73a and 73b that are to be the sources of the p-type nanosheet FETs in the active region 71 are connected to the BM0 interconnect 52 through vias. Also, a portion 74 that is to be the drains of the p-type nanosheet FETs in the active region 71 is connected to the M1 interconnect 62 through a local interconnect, a via, an M0 interconnect, and a via.

Gate interconnects 81a and 81b extend in the Y direction and also extend in the Z direction from the upper part over to the lower part. The gate interconnects 81a and 81b surround the peripheries of the nanosheets 72a and 72b, respectively, in the Y direction and the Z direction through gate insulating films (not shown). The gate interconnects 81a and 81b are to be the gate of the transistor P1, and connected to an interconnect 64 in the M0 layer through vias. The M0 interconnect 64 extends in the X direction from the dummy transistor DN2 over to the dummy transistor DN3. The M0 interconnect 64 is connected to the M1 interconnect 62 through a via.

The configuration of the transistor P2 will be described focusing mainly on the unit on the lower right in the figure.

In the M1 layer, an interconnect 65 extending in the Y direction is formed. In the M2 layer, an interconnect 66 extending in the X direction is formed on the lower side in the figure. The M2 interconnect 66 corresponds to the output terminal OUT. The M1 interconnect 65 is connected to the M2 interconnect 66 through a via.

An active region 76 forming the channels, sources, and drains of p-type nanosheet FETs that are to be the transistor P2 is formed at a position overlapping the BM0 interconnect 52 in planar view.

The active region 76 includes nanosheets 77a and 77b that are to be the channels of the p-type nanosheet FETs. Portions 78a and 78b that are to be the sources of the p-type nanosheet FETs in the active region 76 are connected to the BM0 interconnect 52 through vias. Also, a portion 79 that is to be the drains of the p-type nanosheet FETs in the active region 76 is connected to the M1 interconnect 65 through a local interconnect, a via, an M0 interconnect, and a via.

Gate interconnects 86a and 86b extend in the Y direction and also extend in the Z direction from the upper part over to the lower part. The gate interconnects 86a and 86b surround the peripheries of the nanosheets 77a and 77b, respectively, in the Y direction and the Z direction through gate insulating films (not shown). The gate interconnects 86a and 86b are to be the gate of the transistor P2, and connected to the interconnect 64 in the M0 layer through vias. The M0 interconnect 64 is however not connected to the M1 interconnect 65.

In FIG. 8, an active region 91 forming the channels, sources, and drains of n-type nanosheet FETs is formed at a position overlapping the active region 71 of the transistor P1 in planar view. Also, an active region 96 forming the channels, sources, and drains of n-type nanosheet FETs is formed at a position overlapping the active region 76 of the transistor P2 in planar view. The active regions 91 and 96 constitute the dummy transistors DN2 and DN3, respectively.

The gate interconnects 81a and 81b surround the peripheries of nanosheets in the active region 91 in the Y direction and the Z direction through gate insulating films (not shown). The gate interconnects 86a and 86b surround the peripheries of nanosheets in the active region 96 in the Y direction and the Z direction through gate insulating films (not shown).

Portions that are to be sources and drains in the active region 91 are connected to the M0 interconnect 61 through vias. Portions that are to be sources and drains in the active region 96 are connected to the M0 interconnect 61 through vias.

In addition, in FIG. 9, a dummy transistor DP4 is formed in a region between the transistor P1 and the transistor P2. Also, in FIG. 8, a dummy transistor DN4 is formed at a position overlapping the dummy transistor DP4 in planar view.

The layout structure shown in FIGS. 8 and 9 has features similar to those in the first embodiment. That is, the layouts of the transistors P1 and P2 constituting the current mirror are formed line-symmetrically with respect to the line Y1-Y1′ as the symmetric axis. Specifically, both the transistors P1 and P2 are constituted by 2×2 units arranged in an array where each unit is formed of two transistors connected in parallel. Therefore, the transistors P1 and P2 have the same transistor size. Also, in the transistors P1 and P2, the gates, the sources, and the drains constituting the transistors are placed symmetrically. The interconnects and the vias connected to the transistors are also placed symmetrically. Also, the M2 interconnect 63 corresponding to the node PD and the M2 interconnect 66 corresponding to the output terminal OUT are placed symmetrically with respect to the line Y1-Y1′ as the symmetric axis.

Having the symmetric arrangement as described above, since variations in characteristics between the transistors P1 and P2 are prevented, it is possible to prevent variations in the ratio of the output current to the reference current.

Also, the n-type dummy transistors DN2 and DN3 formed above the transistors P1 and P2 are formed line-symmetrically with respect to the line Y1-Y1′ as the symmetric axis. By forming the dummy transistors DN2 and DN3 symmetrically in their circuits and layouts, variations in the finished sizes of the transistors including the transistors P1 and P2 in the lower part are prevented.

Moreover, since the gates of the transistors P1 and P2 and the overlying dummy transistors DN2 and DN3 are integrally formed, for the gates of the p-type nanosheet FETs constituting the transistors P1 and P2, the gates of their overlying n-type nanosheet FETs also work as loads. In the above configuration, however, since the dummy transistors DN2 and DN3 are also formed symmetrically in their circuits and layouts, variations in loads can be prevented.

As described above, according to this embodiment, the semiconductor integrated circuit device includes the transistors P1 and P2 constituting a current mirror. The transistors P1 and P2 are each constituted by a plurality of units each having an active region. The dummy transistors DN2 and DN3 are formed at positions different from the transistors P1 and P2 in the depth direction. The dummy transistors DN2 and DN3 are each constituted by a plurality of units each having an active region and placed at positions overlapping the units constituting the transistors P1 and P2 in planar view. The active region of the transistor P1 and the active region of the transistor P2 are formed line-symmetrically with respect to the straight line Y1-Y1′ in planar view. The active region of the dummy transistor DN2 and the active region of the dummy transistor DN3 are also formed line-symmetrically with respect to the straight line Y1-Y1′. Also, in the dummy transistors DN2 and DN3, the sources and the drains at the symmetric positions have the same electrical connection state. With this configuration, since variations in the characteristics of the transistors P1 and P2 constituting the current mirror are prevented, it is possible to prevent variations in the ratio of the output current to the reference current.

Note that, as in Alteration 1 of the first embodiment, the active regions 91 and 96 constituting the dummy transistors DN2 and DN3 may be configured not to be connected to the M0 interconnect 61. That is, all of the sources and drains of the dummy transistors DN2 and DN3 may be floating.

Also, as in Alteration 2 of the first embodiment, some of the units of the transistors P1 and P2 constituting the current mirror may be changed to dummy transistors. For example, out of the 2×2 units constituting the transistor P2, two units on the right in the figure may be changed to dummy transistors. In this case, since the transistor size of the transistor P2 is half that of the transistor P1, the relationship between the reference current and the output current is Iout=0.5×Iin.

### Other Embodiments

### (No. 1)

In the embodiments described above, all of the sources and drains of the dummy transistors overlapping the transistors constituting the current mirror in planar view are connected to power supply, or are floating. However, the configuration is not limited to this. For example, all of the sources and drains of the dummy transistors may be connected to a predetermined node other than power supply.

Also, all of the sources and drains of the dummy transistors do not necessarily need to have the same electrical connection state. That is, according to the present disclosure, in the dummy transistors overlapping the transistors constituting the current mirror, it is only required for sources and drains located at line-symmetric positions to have the same electrical connection state. The electrical connection state as used herein may be any of the state connected to power supply, the floating state, and the state connected to a predetermined node other than power supply.

### (No. 2)

In the embodiments described above, the units of the transistors constituting the current mirror each have the same configuration of having two parallel-connected transistors. However, each unit may be constituted by transistors other than two. Also, the numbers of transistors may be made different among the units. That is, for the units of the transistors constituting the current mirror, it is only required to have line-symmetric layouts.

For example, in FIG. 2 of the first embodiment, among the units constituting the transistors N1 and N2, while the upper units in the figure may have the same configuration of having two transistors, the lower units in the figure may have the same configuration of having three transistors.

Also, while 2×2 units are arranged in an array in each of the transistors, the number and arrangement form of the units are not limited to these. For example, the units may be arranged only in the X direction, or may be arranged in an array of 2×3 units or 3×3 units.

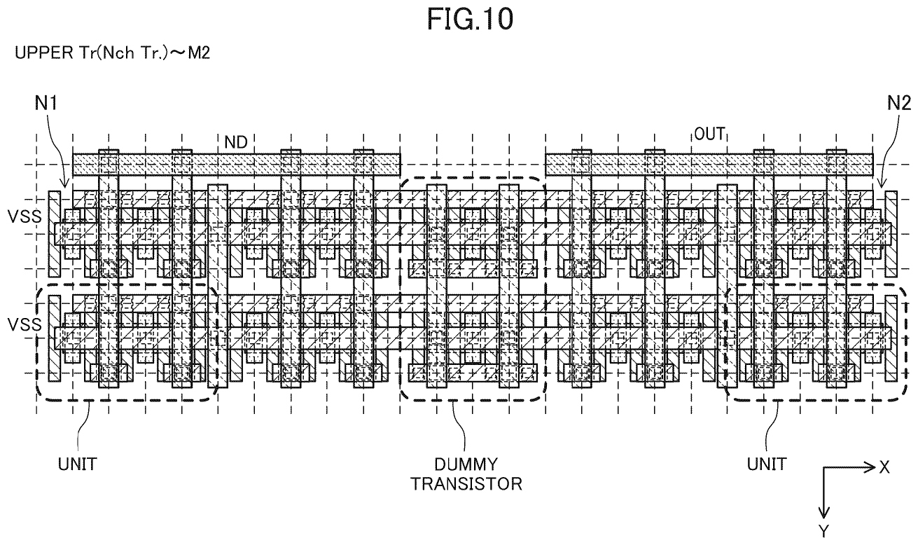

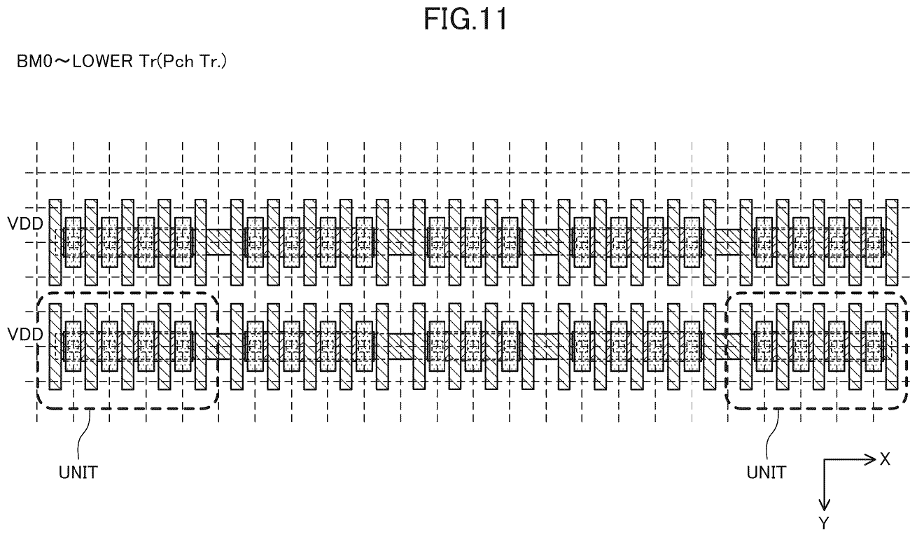

FIGS. 10 and 11 are views showing another layout structure example, using CFETs, of the current mirror of FIG. 1, where FIG. 10 is a plan view of an upper part and FIG. 11 is a plan view of a lower part. In this layout structure example, the units constituting the transistors N1 and N2 are each constituted by three transistors connected in parallel. The other configuration is similar to that shown in FIGS. 2 and 3, and therefore description is omitted here.

### (No. 3)

While the active regions of the units are separated from each other in the above embodiments, they may be formed continuously.

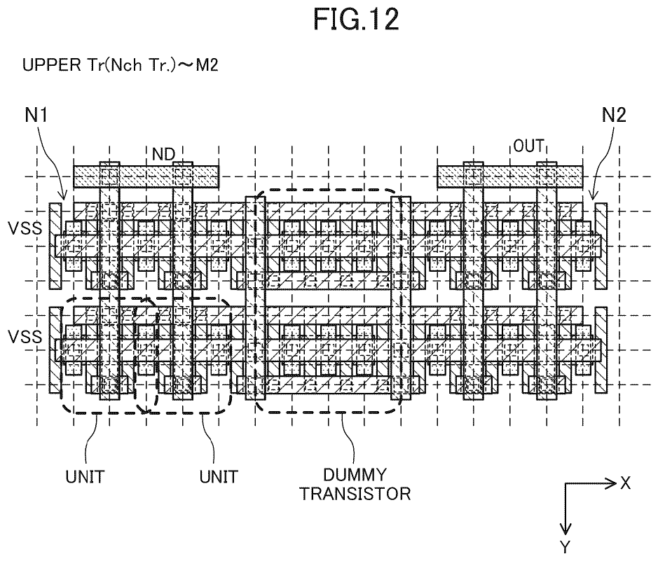

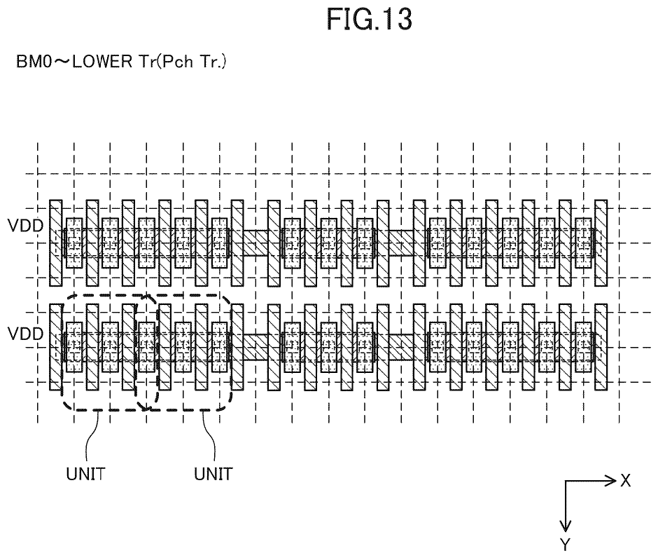

FIGS. 12 and 13 are views showing yet another layout structure example, using CFETs, of the current mirror of FIG. 1, where FIG. 12 is a plan view of an upper part and FIG. 13 is a plan view of a lower part. In this layout structure example, in the transistors N1 and N2, the units adjacent in the X direction share the active region: that is, the active regions of these units are formed continuously. The other configuration is similar to that shown in FIGS. 2 and 3, and therefore description is omitted here.

### (No. 4)

In the embodiments described above, the transistors constituting the current mirror and the dummy transistors overlapping these transistors in planar view have layout structures in which the active regions, the interconnects, and the vias are all line-symmetric. Note however that the effects described in the embodiments can be obtained if only the active regions are line-symmetric even though the interconnects and the vias are not line-symmetric. Also, more effects will be obtained if the local interconnects connected to the active regions are line-symmetric, or more effects will be obtained if the gates of the transistors are line-symmetric. Moreover, variations in the ratio of the output current to the reference current can be prevented more effectively if the interconnects and the vias connected to the transistors are line-symmetric.

In the embodiments descried above, the nanosheet is illustrated to have a structure of three sheets lying one above another and having a rectangular cross-sectional shape. However, the number of sheets and cross-sectional shape of the sheet structure of the nanosheet are not limited to these.

While the transistors are nanosheet FETs in the embodiments described above, the configuration is not limited to this. For example, fin FETs or other types of transistors may be used.

According to the present disclosure, in a current mirror, variations in the ratio of the output current to the reference current can be prevented. The present disclosure is therefore useful for improvement in the performance of a semiconductor integrated circuit device, for example.

1. A semiconductor integrated circuit device, comprising:
a first transistor of a first conductivity type having a source connected to power supply and a gate and a drain connected to a first node;
a second transistor of the first conductivity type located at a same position as the first transistor in a depth direction and having a source connected to power supply, a gate connected to the first node, and a drain connected to an output terminal;
a first dummy transistor of a second conductivity type located at a different position from the first transistor in the depth direction and having a gate connected to the first node; and
a second dummy transistor of the second conductivity type located at a same position as the first dummy transistor in the depth direction and having a gate connected to the first node, wherein
the first and second transistors are each constituted by a plurality of units each having an active region forming a channel, source, and drain of a transistor,
the first and second dummy transistors are each constituted by a plurality of units each having an active region forming a channel, source, and drain of a transistor, the plurality of units being placed at positions overlapping the corresponding units constituting the first and second transistors in planar view,
the active region of the first transistor and the active region of the second transistor are formed line-symmetrically with respect to a predetermined straight line as an axis in planar view,
the active region of the first dummy transistor and the active region of the second dummy transistor are formed line-symmetrically with respect to the predetermined straight line in planar view, and
in the first and second dummy transistors, the sources and the drains located at symmetric positions with respect to the predetermined straight line have a same electrical connection state.

2. The semiconductor integrated circuit device of claim 1, wherein
the electrical connection state is any of being connected to power supply, being floating, and being connected to a predetermined node other than power supply.

3. The semiconductor integrated circuit device of claim 1, wherein
a local interconnect connected to the active region of the first transistor and a local interconnect connected to the active region of the second transistor are formed line-symmetrically with respect to the predetermined straight line in planar view, and
a local interconnect connected to the active region of the first dummy transistor and a local interconnect connected to the active region of the second dummy transistor are formed line-symmetrically with respect to the predetermined straight line in planar view.

4. The semiconductor integrated circuit device of claim 1, wherein
the gate of the first transistor and the gate of the second transistor are formed line-symmetrically with respect to the predetermined straight line in planar view, and
the gate of the first dummy transistor and the gate of the second dummy transistor are formed line-symmetrically with respect to the predetermined straight line in planar view.
